(19) United States
(12) Patent Application Publication
(10) Pub. No.: US 2012/0007035 A1
(43) Pub. Date: Jan. 12, 2012

(54) Intrinsic Programming Current Control for a RRAM

(75) Inventors: Sung Hyun JO, Sunnyvale, CA (US); Wei Lu, Ann Arbor, MI (US)

(73) Assignee: Crossbar, Inc., Menlo Park, CA (US)

(21) Appl. No.: 12/834,610

(22) Filed: Jul. 12, 2010

(51) Int. Cl. H01L 45/00; H01L 21/02

(52) U.S. Cl. 257/4; 438/382; 257/E45.001; 257/E21.004

(57) ABSTRACT

A resistive switching device. The device includes a substrate and a first dielectric material overlying a surface region of the substrate. The device includes a first electrode overlying the first dielectric material and an optional buffer layer overlying the first electrode. The device includes a second electrode structure. The second electrode includes at least a silver material. In a specific embodiment, a switching material overlies the optional buffer layer and disposed between the first electrode and the second electrode. The switching material comprises an amorphous silicon material in a specific embodiment. The amorphous silicon material is characterized by a plurality of defect sites and a defect density. The defect density is configured to intrinsically control programming current for the device.

### CROSS REFERENCE TO RELATED APPLICATIONS

N/A

### STATEMENT RELATED TO FEDERALLY SPONSORED RESEARCH OR DEVELOPMENT

N/A

### REFERENCE TO A “SEQUENCE LISTING,” A TABLE, OR A COMPUTER PROGRAM LISTING APPENDIX SUBMITTED ON COMPACT DISC

N/A

### BACKGROUND

The present invention is related to switching devices. More particularly, the present invention provides a structure and a method for forming a resistive switching memory device. The resistive switching memory device is characterized by an intrinsic programming current control and high endurance, among others.

The success of semiconductor devices has been mainly driven by an intensive transistor down-scaling process. However, as field effect transistors (FET) approach sizes less than 100 nm, problems such as short channel effect start to prevent proper device operation. Moreover, such sub 100 nm device size can lead to sub-threshold slope non-scaling and also increases power dissipation. It is generally believed that transistor based memories such as those commonly known as Flash may approach an end to scaling within a decade. Flash memory is one type of non-volatile memory device.

Other non-volatile random access memory (RAM) devices such as ferroelectric RAM (Fe RAM), magneto-resistive RAM (MRAM), organic RAM (ORAM), and phase change RAM (PCRAM), among others, have been explored as next generation memory devices. These devices often require new materials and device structures to couple with silicon based devices to form a memory cell, which lack one or more key attributes. For example, Fe-RAM and MRAM devices have fast switching characteristics and good programming endurance, but their fabrication is not CMOS compatible and size is usually large. Switching for a PCRAM device uses Joules heating, which inherently has high power consumption. Organic RAM or ORAM is incompatible with large volume silicon based fabrication and device reliability is usually poor.

From the above, an improved semiconductor memory device and techniques are therefore desirable.

### BRIEF SUMMARY OF THE PRESENT INVENTION

The present invention is related to switching devices. More particularly, the present invention provides a structure and a method for forming a resistive switching memory device. The resistive switching memory device is characterized by an intrinsic programming current control and high endurance.

In a specific embodiment, a switching device is provided. The switching device includes a substrate and a first dielectric material overlying a surface region of the substrate. A first electrode structure overlies the first dielectric material and a buffer layer overlies the first electrode. The switching device includes a second electrode structure comprising at least a silver material. In a specific embodiment, the switching device includes a switching material disposed between the first electrode and the second electrode and overlies the buffer layer. In a specific embodiment, the switching material includes an amorphous silicon material characterized by a plurality of defect sites and a defect density. The plurality of defect sites and the defect density determine an on state current of the switching device thus endurance characteristic in a specific embodiment.

In a specific embodiment, a method for forming a switching device is provided. The method includes providing a semiconductor substrate having a surface region and forming a dielectric layer overlying the surface region of the semiconductor substrate. The method forms a bottom electrode structure overlying the dielectric layer. In a specific embodiment, the method includes depositing a switching material comprising an amorphous silicon material overlying the bottom electrode using a deposition process. The deposition process is performed at a deposition temperature in a specific embodiment. In a specific embodiment, the deposition process causes a plurality of defect sites to form in the amorphous silicon material. A top electrode structure comprising a metal material is formed overlying the switching material.

Many benefits are achieved by ways of present invention over conventional techniques. For example, the present resistive switching device can be fabricated using conventional equipment and processes. In addition, the present device has an intrinsic programming current control to enhance device performance, for example, an increased R_{off} to Rₒₙ ratio by intrinsically adjusting both off state resistance and on state resistance. This is especially useful in reducing power for writing, erasing and reading the device while maintaining a desirable high R_{off} to Rₒₙ ratio. Depending on the embodiment, one or more of these benefits may be realized. One skilled in the art would recognize other variations, modifications and alternatives.

### SUMMARY OF THE DRAWINGS

FIG. 1 is a simplified diagram illustrating a resistive switching device according to an embodiment of the present invention.

FIG. 2 is a simplified diagram illustrating a resistive switching device at an off state according to an embodiment of the present invention.

FIG. 3 is a simplified diagram illustrating a resistive switching device at an on state according to an embodiment of the present invention.

FIGS. 4-6 are simplified current versus voltage plots of the switching device according to an embodiment of the present invention.

### DETAILED DESCRIPTION OF THE PRESENT INVENTION

The present invention is related to switching devices. More particularly, the present invention provides a structure and a method for forming a resistive switching memory device. The resistive switching memory device is characterized by an intrinsic programming current control and high endurance.

Resistive switching in an amorphous silicon based resistive random access memory (RRAM) is caused by metal particle injection from a metal electrode into the amorphous silicon material. When the device is in on state, the metal particles form a filament structure in the amorphous silicon material. When a voltage is applied, electrons can tunnel from one metal particle to a neighboring metal particle allowing a tunneling current to flow along the filament structure. At an off state, the filament structure becomes discontinued that very low current flows in the amorphous silicon material and the device is in a high resistance state. As tunneling current has an exponential dependence on distance between metal particles, the on state current and the off state current can be controlled by optimizing the distance between metal particles.

Programming current in the resistive switching device during a write process can be controlled by using a current compliance or can be monitored by addition of an external series resistor. Depending on RRAM types, applying the current compliance or adding an external series resistor can affect the on state resistance of the device. In the case where the current compliance or serial resistor do not have any effect on the on state resistance, the power consumption for the write process is reduced by the compliance. However, the power consumption for an erase process is not affected, since no current compliance has to be used to apply large electric field across the device or to generate Joule heating inside the device during the erase process. Furthermore, the power consumption for a read process is also not reduced as on state resistance is independent of the current compliance or the series resistor. In the case where the on state resistance is increased by the current compliance, power consumptions for write, erase, or read are reduced. But, as only on state resistance is increased, and off state resistance is not affected, a ratio of off resistance to on resistance (R_{off}/Rₒₙ) is reduced, which is undesirable. A high R_{off} to Rₒₙ ratio (greater than 10³) is required for reliable switching. Therefore control of the switching device programming using an external device may have unintended disadvantages.

Embodiments according to the present invention provide a method and device structure to intrinsically control programming currents for writing, for reading, and for erasing. In certain application a current compliance can be used to further enhance the reliability and endurance of the device. One skilled in the art would recognize other variations, modifications, and alternatives.

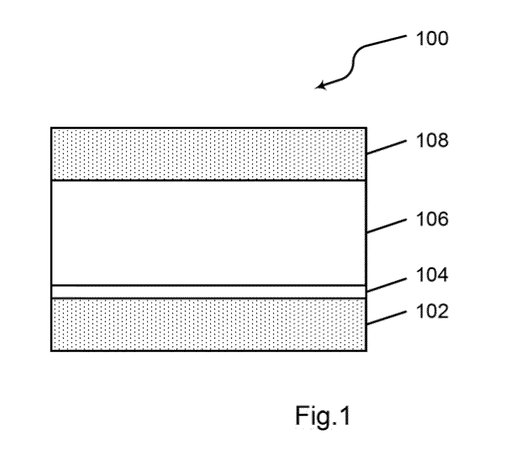

FIG. 1 is a simplified diagram illustrating a resistive switching device 100 according to an embodiment of the present invention. As shown, the resistive switching device includes a bottom electrode 102. The bottom electrode can be a first metal material or a doped semiconductor material depending on the application. The first metal material can be those commonly used as interconnects in semiconductor device fabrication such as copper, tungsten, or aluminum depending on the application. In certain implementation, the metal material can also include one or more adhesion layer or barrier layer to prevent diffusion of the metal material to other parts of the device.

The resistive switching device includes a switching material 106 overlying the bottom electrode. The switching material can be an amorphous silicon material having an semiconductor characteristic in a specific embodiment. Other switching materials such as a suitable metal oxide may also be used depending on the application. In a specific embodiment, the switching device includes a top electrode 108 overlying the switching material. The top electrode can be a second metal material in a specific embodiment. The top electrode can also be a combination of more than one metal layers depending on the embodiment. In a specific embodiment the top electrode includes a silver material for amorphous silicon as a switching material.

As shown in FIG. 1, the resistive switching device can include a buffer layer 104 between the switching material and the bottom electrode. In the absence of the buffer layer, an interface region formed between the amorphous silicon material and the first metal material can have a high defect level due to material mismatch. This high defect level can affect device reliability and performance. In other embodiments, the high defect level in the interface region may also be exploited to form one time programmable (OTP) devices.

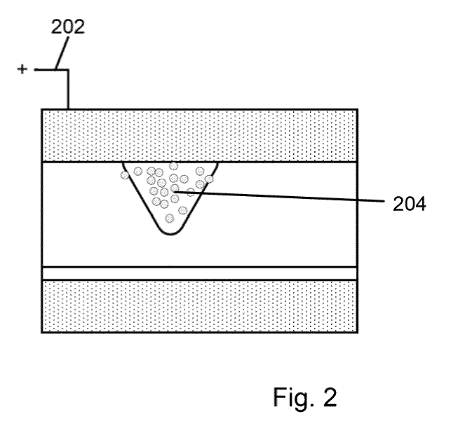

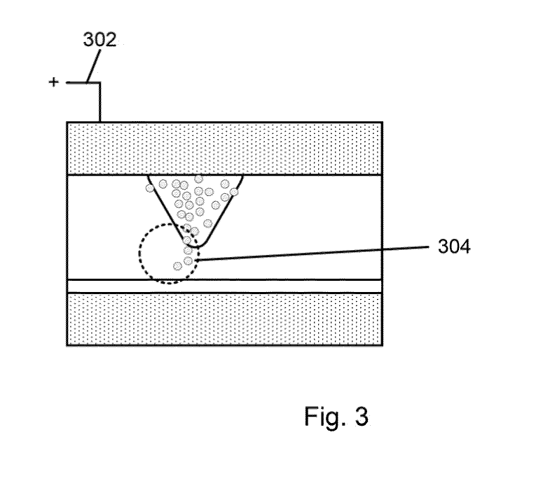

FIGS. 2-3 are simplified diagrams illustrating operations of the resistive switching device and control of the programming current according to an embodiment of the present invention. The embodiment is exemplified using an amorphous silicon material as the switching material and a silver metal as at least a portion of the top electrode.

As shown in FIG. 2, a first voltage 202 is applied to the top electrode of the as-fabricated resistive switching device. For an amorphous silicon switching material and a silver top electrode, the first voltage is a positive voltage. When the first voltage is greater than about an electroforming voltage, a plurality of metal particles are injected from the top electrode to form a metallic region 204 in a portion of the switching material in an electroforming process. As shown, the metallic region is formed in a vicinity of the top electrode surface and not in contact with the bottom electrode at this time. The device is now at an off state characterized by an off state resistance and an off state current through the device. The off state current is usually negligible as the metal region is formed near the top electrode surface.

Referring now to FIG. 3, to change the device into an on state, or a low resistance state, a second voltage 302 is applied to the top electrode. The second voltage is a positive voltage in a specific embodiment. The second voltage can range from about one volt to about four volts for a silver/amorphous silicon/p+ polysilicon device in a specific embodiment. As shown, a filament region 304 is formed extending from the metallic region towards the bottom electrode allowing an on state current to flow. The on state current results from tunneling current as electrons tunnels from a metal particle to a neighboring metal particle in the filament structure. As tunneling current is exponentially related to the distance between metal particles, a larger current would result if the metal particles are close to each other. When a negative voltage is applied to the top electrode, the metal filament structure would retract or become non-continuous and the device is back to the off state and has an off state resistance.

In a specific embodiment, the metal particles are formed in the defect sites of the amorphous silicon material. The defect sites can be grain boundary, silicon dangling bonds, atomic dislocations, molecular dislocations, or dislocations in crystalline plane, including any combination of these. Therefore, the number of defect sites and the defect density in the amorphous silicon material directly affect the metal filament structure and its formation at on state or off state.

In a specific embodiment, the defect density in the amorphous silicon material can be controlled by changing deposition process or deposition conditions. In a specific embodiment, the amorphous silicon material can be formed by a chemical vapor deposition process using for example silane (SiH₄), chlorosilane, or others as silicon source. Defects as a result of silicon dangling bonds may be reduced by using a hydrogen bearing species, for example, silane or by adding a hydrogen gas during deposition.

In other embodiments, defect density in amorphous silicon material may be controlled by using different substrate temperatures for deposition. At lower temperatures (less than about 220 Degree Celsius), hydrogen species do not have sufficient energy to form a bond with silicon and the defect density is high. Defect density is high at low deposition temperature process, for example less than 220 Degree Celsius using plasma enhanced chemical vapor deposition (PECVD). As substrate temperature is increased, at temperature greater than about 270 Degree Celsius, hydrogen species diffuse out of the amorphous silicon material and the defect density is again increased. The defect density of amorphous silicon material deposited using a relatively high temperature process (for example greater than about 270 Degree Celsius) such as lower pressure chemical vapor deposition (LPCVD) process is therefore high. The lowest defect density observed in amorphous silicon material is deposited by PECVD at a temperature ranges from about 220 to about 270 Degree Celsius.

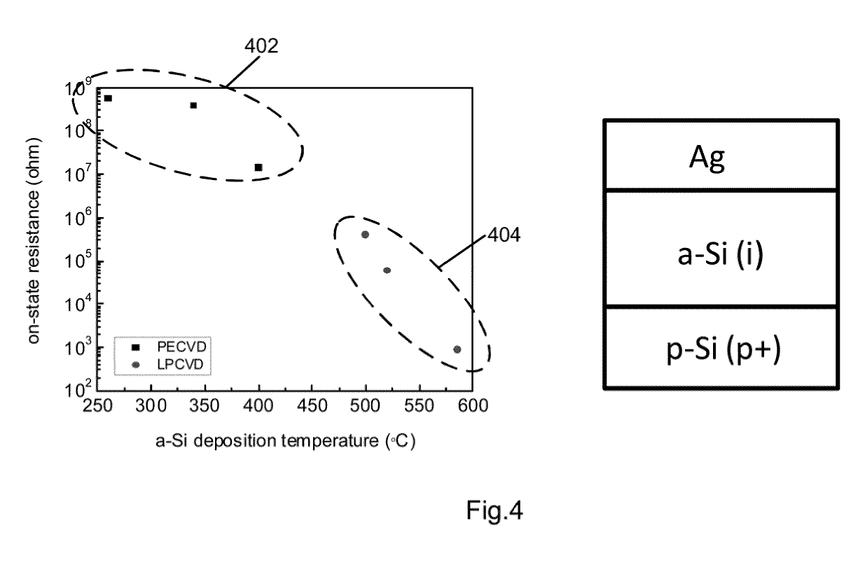

Depending on the embodiment, switching characteristic of the switching device can also be controlled. FIGS. 4-6 are experimental results on the switching characteristics according to embodiments of the present invention.

As shown in FIG. 4, a simplified plot of dependence of on state resistance on deposition temperature of amorphous silicon material is illustrated. The device size under study ranges from about 50 nm by 50 nm to about 200 nm by 200 nm. As the deposition temperature of the amorphous silicon is between about 250 Degree Celsius and 400 Degree Celsius in data set 402, the device has an on state resistance ranging from about 10⁷ ohms to about 10⁹ ohms, and the device exhibits a rectifying switching characteristics. When the deposition temperature is greater than about 500 Degree Celsius as in data set 404, the device has an on state resistance ranging from about 10³ ohms to about 10⁵ ohms, and the device exhibits a non-rectifying switching characteristics.

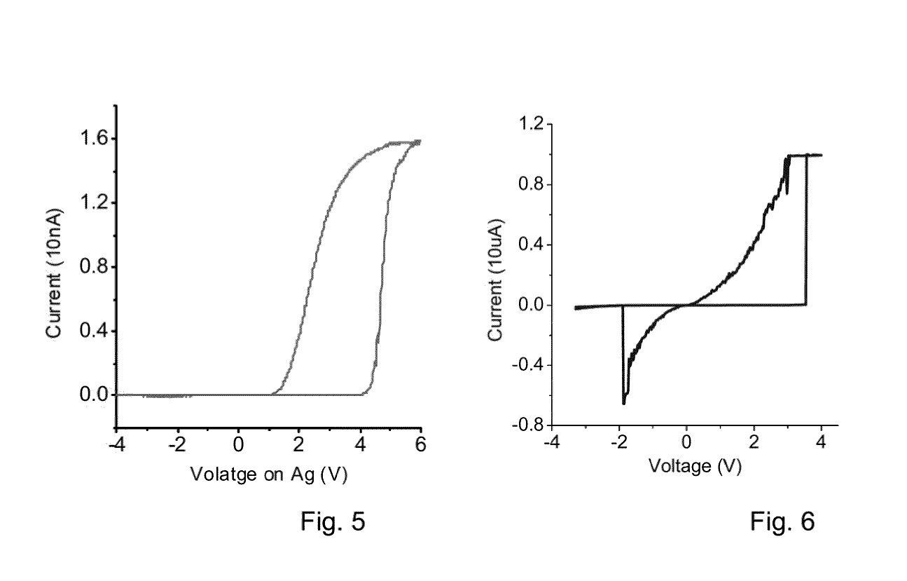

Switching behavior of the device can be correlated to amorphous silicon defect density as further illustrated in Current vs voltage (I-V) characteristics as shown in FIGS. 5 and 6. When the amorphous silicon material is deposited at about 260 Degree Celsius, corresponding to a low defect density in the amorphous silicon material, the on state current of the resistive switching device is low as the metal particles are far apart to one another. The resistive switching device exhibits a rectifying switching behavior. That is the device is turned on and current flows when a first voltage (greater than about 3 volts) is applied to the device, while a voltage opposite in polarity to the first voltage is applied, the device is turned off and no current flows. A resistive switching device using amorphous silicon deposited at temperatures between 220 Degree Celsius and 400 Degree Celsius or having a low defect density exhibits a rectifying switching behavior as shown in FIG. 5.

FIG. 6 shows an I-V characteristic of a resistive switching device using amorphous silicon material deposited at a temperature of 530 Degree Celsius, which has a high defect density in a specific embodiment. The device has a high on state current and exhibits a non-rectifying switching behavior. That is when a positive voltage is applied, current flows from the top electrode to the bottom electrode, and current flows in an opposite direction when under a reverse bias condition as shown in FIG. 7. Note that the current scale in FIG. 5 is in 10 nA and the current scale in FIG. 6 is in 10 μA. Of cause one skilled in the art would recognize other variations, modifications, and alternatives.

In a specific embodiment, a method of forming a resistive switching device is provided. The method includes providing a semiconductor substrate having a surface region and forming a dielectric layer overlying the surface region. The semiconductor substrate can be a single crystal silicon, silicon germanium, silicon on insulator, and others, depending on the embodiment. The dielectric layer can be silicon oxide, silicon nitride, or a dielectric stack (for example, an oxide on nitride on oxide commonly known as ONO, depending on the embodiment. The dielectric layer may be deposited using techniques such as chemical vapor deposition (CVD) including low pressure CVD, plasma enhanced CVD, and other suitable deposition process. In certain embodiments, the semiconductor substrate can have one or more devices, for example CMOS devices formed thereon. The resistive switching device can be operably coupled to the one or more CMOS devices depending on the application.

In a specific embodiment, the method includes forming a bottom electrode structure overlying the dielectric layer. The bottom electrode structure usually includes an adhesive layer or a diffusion barrier layer and a metal material. The adhesive layer or the diffusion barrier layer can be titanium, titanium nitride, tantalum, tantalum nitride or tungsten nitride, and the likes. The metal material can be commonly used metal material for semiconductor processing, for example, copper, tungsten, aluminum, and others.

The method includes depositing a switching material overlying the bottom electrode using a deposition process. In a specific embodiment, the switching material can be an amorphous silicon material. The amorphous silicon material can be deposited using a plasma enhanced chemical vapor deposition process or a low pressure chemical vapor deposition process, or other suitable deposition techniques. Depending on the embodiment, silicon precursors such as silane or disilane, or a chlorosilane may be used. In a specific embodiment, the amorphous silicon material is deposited at a deposition temperature. In a specific embodiment, the deposition process including the deposition temperature forms a plurality of defect sites in the amorphous silicon material. The plurality of defect sites can include silicon dangling bonds, dislocation of atoms, dislocation of molecules, dislocation of clusters and others. In a specific embodiment, defect sites and defect density caused by silicon dangle bonds can be controlled by the deposition process and the deposition temperature. For example, the number of defect sites decreases when a hydrogen bearing species is present in the chemical vapor deposition process. The hydrogen species may be provided using silane or disaline, and the likes. In certain embodiment, a small amount of hydrogen gas may be included during the deposition process. The hydrogen atoms react with the silicon dangling bonds and cause the number of defect sites to decrease in a specific embodiment.

Depending on the embodiment, defect sites due to silicon dangling bonds may be controlled by deposition temperature. At low deposition temperatures, for example, less than about 220 Degree Celsius, hydrogen species do not have sufficient energy to form a bond with silicon dangling bond and the defect density is therefore high. In a specific embodiment, defect density is high at low deposition temperature process, for example less than 220 Degree Celsius using plasma enhanced chemical vapor deposition (PECVD). As deposition temperature is increased, at temperature greater than about 270 Degree Celsius, hydrogen species gain enough energy to diffuse out of the amorphous silicon material and the defect density is again increased. The defect density of amorphous silicon material deposited using a relatively high temperature process (for example greater than about 270 Degree Celsius) such as lower pressure chemical vapor deposition (LPCVD) process is therefore high. The lowest defect density observed in amorphous silicon material is deposited by PECVD at a temperature ranges from about 220 to about 270 Degree Celsius. Of course one skilled in the art would recognize other modifications, variations, and alternatives.

In a specific embodiment, the method includes forming a top electrode structure overlying the switching material. The top electrode has a portion that includes at least a conductive material overlying the switching material and in contact with the switching material in a specific embodiment. Depending on the embodiment, the top electrode can further include a wiring structure to connect with other switching devices, or other devices. For amorphous silicon material as the switching material, the conductive material can be silver, gold, platinum, palladium, nickel or others. Upon application of an electroforming voltage or forming voltage, the conductor material forms a metal region near the top electrode structure. The metal region includes a filament structure extending from the metal region towards the bottom electrode. The filament structure extends in length upon application of a first voltage and the switching material is at a low resistant state and an on state current flows. When a reversed bias voltage, that is opposite in polarity to the first voltage is applied, the filament structure retracts and the switching material revert back to the high resistant state. The on state current is caused by electrons tunneling from a metal particle to a neighboring metal particle upon application of the first voltage. As the conductive material is trapped in the defect sites of the amorphous silicon material, a high defect density would enable a high on state current for a given applied voltage as metal particles are closer to each other. Of course one skilled in the art would recognize other modifications, variations, and alternatives.

Though the present invention has been described using various examples and embodiments, it is also understood that the examples and embodiments described herein are for illustrative purposes only and that various modifications or alternatives in light thereof will be suggested to persons skilled in the art and are to be included within the spirit and purview of this application and scope of the appended claims.

What is claimed is:

1. A resistive switching device, comprising:
a substrate comprising a surface region;
a first dielectric material overlying the surface region of the substrate;
a first electrode overlying the first dielectric material;
a buffer layer overlying the first electrode;
a second electrode structure comprising at least a silver material; and
a switching material disposed between the first electrode and the second electrode overlying the buffer layer, the switching material comprising an amorphous silicon material, the amorphous silicon material being characterized by a plurality of defect sites and a defect density, the defect density being configured to control a programming current provided by a programming voltage coupled to the first electrode and the second electrode, the defect density being defined by a silicon dangling bond density.

2. The device of claim 1 wherein the plurality of defect sites in the amorphous silicon material are further caused by atomic dislocations, molecular dislocations, or cluster dislocations.

3. The device of claim 1 wherein the silicon dangling bond density is controlled by a deposition temperature of the amorphous silicon material.

4. The device of claim 1 wherein the silicon dangling bond density is reduced by a hydrogen species in a deposition process, the hydrogen species being provided by silane, disilane, or a hydrogen gas.

5. The device of claim 1 wherein the silicon dangling bond density ranges from about 10e13 to about 10e19 cm⁻³.

6. The device of claim 1 wherein the programming current is a write current, a read current or an erase current.

7. The device of claim 1 wherein the silver material forms a plurality of sliver particles in a portion of the switching material when a first voltage is applied to the second electrode, the first voltage being a positive voltage.

8. The device of claim 1 wherein the plurality of silver particles form a metal region in a portion of the amorphous silicon material upon application of the first voltage.

9. The device of claim 8 wherein the first voltage causes the device resistance to change from an as-fabricated device resistance to an off state resistance, the off state resistance being a high resistance state.

10. The device of claim 8 wherein the first voltage is an electroforming voltage.

11. The device of claim 1 wherein the plurality of silver particles form a filament structure extending from the metal region towards the first electrode and not in contact with the first electrode upon application of a second voltage to the second electrode structure.

12. The device of claim 11 wherein the second voltage causes a low resistance state and the second voltage causes an on state current to flow from the second electrode to the first electrode.

13. The device of claim 11 wherein the filament structure is characterized by a length and a distance between silver particles.

14. The device of claim 1 wherein the distance between silver particles determines an amplitude of the on state current flow upon application of the second voltage.

15. The device of claim 14 wherein the amplitude of the on state current determines a switching characteristic, wherein a low on state current provides a rectifying switching and a high on state current provides a non-rectifying switching.

16. The device of claim 15 wherein the low on state current is less than about microampere range and a high on state current is larger than about 10 microampere range.

17. The device of claim 1 wherein the plurality of silver particles is formed in the defect sites of the amorphous silicon material.

18. The device of claim 13 wherein the distance between silver particles is determined by the defect density of the amorphous silicon material.

19. The device of claim 1 wherein the on state current is dependent at least on the defect density.

20. The device of claim 1 wherein the off state resistance is dependent at least on the defect density.

21. The device of claim 11 wherein the length of the filament structure retracts or the filament structure loses continuity when a third voltage having an opposite polarity to the second voltage is applied to the second electrode.

22. The device of claim 1 wherein the substrate is a semiconductor substrate having one or more CMOS devices formed thereon, the one or more CMOS devices being operably coupled to the switching device.

23. The device of claim 1 wherein the first dielectric material is a silicon oxide material, a silicon nitride material, or a dielectric stack, or a combination.

24. The device of claim 1 wherein the buffer layer comprises a polysilicon material having a p+ impurity characteristic.

25. The device of claim 1 wherein the buffer layer is optional.

26. The device of claim 1 wherein the buffer layer controls an interfacial defect density between the switching material and the bottom electrode.

27. The device of claim 1 wherein at least a portion of the first electrode comprises copper, tungsten, or aluminum.

28. The device of claim 1 wherein at least a portion of the second electrode comprises copper, tungsten, or aluminum.

29. The device of claim 1 wherein the plurality of defect sites in the amorphous silicon material further comprises dislocation of atoms, dislocation of molecules, or dislocation of clusters.

30. The device of claim 1 wherein the silver material forms a plurality of silver particles trapped in the defect sites of the amorphous silicon material, the density of silver particles being determined by the defect density of the amorphous silicon material.

31. A method of forming a resistive switching device, comprising:
providing a substrate having a surface region;
forming a dielectric layer overlying the surface region;
forming a bottom electrode structure overlying the dielectric layer;
depositing a switching material comprising an amorphous silicon material overlying the bottom electrode using a deposition process at a deposition temperature, the deposition process causing a plurality of defect sites in the amorphous silicon material; and
forming a top electrode structure comprising a metal material overlying the switching material.

32. The method of claim 31 wherein the substrate is a semiconductor substrate selected from single crystal silicon, silicon germanium, and silicon on insulator.

33. The method of claim 31 wherein the dielectric layer comprises silicon oxide, silicon nitride, or a silicon oxide on silicon nitride stack.

34. The method of claim 31 wherein bottom electrode structure comprises tungsten, aluminum, or copper.

35. The method of claim 31 wherein the top electrode comprises at least a silver material.

36. The method of claim 31 wherein the deposition process is a plasma enhanced chemical vapor deposition process or a low pressure chemical vapor deposition process using silane, or a chlorosilane as silicon precursor.

37. The method of claim 31 wherein the plurality of defect sites are caused by at least a plurality of silicon dangling bonds.

38. The method of claim 37 wherein the number of silicon dangling bonds decreases when a hydrogen bearing species is used in the chemical vapor deposition process, the hydrogen bearing species comprises silane or a hydrogen gas.

39. The method of claim 31 wherein the defect density is controlled by the deposition temperature wherein a low defect density being formed at a deposition temperature ranging from about 220 Degree Celsius to about 270 Degree Celsius.
